(19) United States
(12) Patent Application Publication
(10) Pub. No.: US 2006/0185836 A1
(43) Pub. Date: Aug. 24, 2006

(54) Thermally coupled surfaces having controlled minimum clearance

(76) Inventor: Scott Garner, Lititz, PA (US)

Correspondence Address: DUANE MORRIS LLP;IP DEPARTMENT, 30 SOUTH 17TH STREET, PHILADELPHIA, PA, 19103-4196, US

(21) Appl. No.: 11/065,466

(22) Filed: Feb. 24, 2005

(51) Int. Cl. H05K 7/20

(52) U.S. Cl. 165/185; 361/705

(57) ABSTRACT

A conformable, thermally conductive layer is provided comprising a flowable component and a plurality of substantially incompressible spacer particles, wherein the conductive layer is disposed between a pair of heat exchange surfaces of an electronic device to maintain a desired spacing during operation. The thermally conductive layer enhances heat transfer between the surfaces while the spacer layer ensures a constant desired offset between the surfaces both to maintain an optimum level of heat transfer and to provide a desired voltage standoff between the surfaces to prevent arcing across the surfaces. The offset is substantially equal to the diameter of the spacer particles, and the particles align in a single layer between the heat exchange surfaces. The heat exchange surfaces can be a heat source such as an integrated circuit chip, and the heat sink can be a plate with a plurality of fins. The flowable component can be a thermal grease or paste, and the spacer particles can be ceramic or glass material. A method of applying the conductive layer and of assembling the heat source and heat sink is also disclosed.

### FIELD OF THE INVENTION

This invention deals generally with thermally conductive, electrically insulating interface layers for coupling heat sinks to semiconductor chips or other electrical devices.

### BACKGROUND OF THE INVENTION

Heat removal from integrated circuits (ICs, or “chips”) has long been an important design consideration because of the need to maintain the components at a sufficiently low operating temperature to ensure continued device reliability. As IC chip geometries are scaled down and operating speeds are increased, the resulting increase in power density exacerbates the problem of heat removal. Thus, the ability to adequately cool these chips has become a limiting factor to increased system performance. Common techniques for removing heat from high-power ICs make use of a cooling device (e.g. heat sink fin or plates, etc.) which is operatively connected to the chip. Heat may be dissipated from the cooling device using a variety of methods, including forced air cooling, circulation of liquid coolants, or through the use of heat pipe technology. For effective cooling, it is important to minimize the thermal resistance between the chip and the heat sink so as to maximize the heat transferred from the chip to the sink, thus assuring the continued reliable operation of the device.

To minimize this thermal resistance, a thermally conductive paste, grease or similar deformable, compliant, thermally conductive material can be placed between the IC chip (i.e. the heat source) and the heat sink. The benefit of using such a compliant material is that it maximizes the surface area between the heat source and heat sink available for thermal conduction. Gaps between the source and sink (e.g. due to surface discontinuities, defects, etc.), reduce the total contact area between the surfaces, which in turn reduces the area available for conductive heat transfer between the components. Thermally conductive paste or grease is highly conformable, and thus can be used to fill these gaps, thereby maximizing the heat transfer area and facilitating faster, more efficient cooling of the heat source.

Another important concern when employing metal heat sink components to cool IC chips is the danger of causing an electrical short in the chip or its connections due to the conduction of electricity through the sink and into the chip itself. Thus, where thermally conductive materials are used between the heat source and sink, it is also desirable that these materials be substantially electrically insulating, to reduce or eliminate the chance for electrical conduction from the heat sink to the chip. As a further protection, the components must be separated by a minimum distance (i.e. a “voltage standoff”) to ensure that electrical “arcing” or arc discharge does not occur across the gap. The need for electrical insulation must, however, be balanced by the need to maximize thermal conduction between the source and sink. Providing a thicker layer of thermally conductive material, while reducing the overall likelihood for shorts between the components, can have the unwanted effect of reducing heat transfer between the components to an unacceptable level.

This is further complicated by the inherent variability in the manufacturing process, in which the stack-up of machining tolerances of the heat sink and heat source can make it difficult to precisely predict and thus control the size of the ultimate gap between the components. With current devices, in order to assure that the thickness of the thermally conductive material is never less than the minimum spacing required for voltage offset, the thickness designed into the system must actually be the design spacing plus the maximum tolerance stack-up. Unfortunately, this can lead to a situation in which the actual spacing between components is much greater than the desired minimum.

Thus, there is a need for a highly conformable thermally conductive material that provides and maintains a desired spacing between a heat sink and a heat source, while providing a high degree of thermal conductivity and a low degree of electrical conductivity.

### SUMMARY OF THE INVENTION

A thermally conductive composition is disclosed for controlling heat transfer between first and second components. The composition can comprise a flowable component and a plurality of spacer members, the spacer members being of substantially uniform size and having a first dimension. The spacer members further can be substantially incompressible, and the first dimension can be selectable to provide an offset between the first and second components when a quantity of the composition is disposed between opposing surfaces of the components and the surfaces engage the plurality of spacer members. The flowable component is also selectable to provide a desired rate of heat transfer between the first and second components when the first and second components are separated by the offset amount.

A component structure is also disclosed comprising a heat source having a major surface, a heat sink having a major surface oriented parallel to the heat source major surface, and a thermally conductive layer comprising a flowable component and a particulate component. The flowable component can have a first coefficient of thermal conductivity and the particulate component can comprise a plurality of spacer members of substantially uniform size. Each of the plurality of spacer members can have a first dimension and can also be substantially incompressible. The major surfaces of the heat source and heat sink can be offset by the layer of thermally conductive material by a distance substantially equal to the first dimension of the spacer members.

A method is further disclosed for providing a desired heat transfer between first and second components. The method can comprise the steps of: providing a heat source having a contact surface; providing a heat sink having a contact surface; and providing a thermally conductive material comprising a flowable component and a particulate component. The particulate component can comprise a plurality of spacer members of substantially uniform size, and each of said plurality of spacer members can have a first dimension. The spacer members further can be substantially incompressible. The contact surfaces of the heat source and heat sink are then engaged with a layer of the thermally conductive material by placing a quantity of the thermally conductive material on one of the contact surfaces and drawing the surfaces together until they engage the plurality of spacer members to provide an offset between the surfaces that is substantially equal to the first dimension of the plurality of spacer members.

### BRIEF DESCRIPTION OF THE DRAWINGS

These and other features and advantages of the present invention will be more fully disclosed in, or rendered obvious by, the following detailed description of the preferred embodiment of the invention, which is to be considered together with the accompanying drawings wherein like numbers refer to like parts and further wherein:

FIG. 1 is a side view of a heat source, heat sink and a thermally conductive, electrically insulating layer including spacer particles therebetween;

FIG. 2 is a side view of a flip chip package incorporating the thermally conductive, electrically insulating layer of FIG. 1; and

FIG. 3 is a side view of an apparatus for applying pressure between heat source and heat sink components which are separated by the thermally conductive, electrically insulating layer of FIG. 1.

### DETAILED DESCRIPTION OF THE PREFERRED EMBODIMENT

This description of preferred embodiments is intended to be read in connection with the accompanying drawings, which are to be considered part of the entire written description of this invention. The drawing figures are not necessarily to scale and certain features of the invention may be shown exaggerated in scale or in somewhat schematic form in the interest of clarity and conciseness. In the description, relative terms such as “horizontal,” “vertical,” “up,” “down,” “top” and “bottom” as well as derivatives thereof (e.g., “horizontally,” “downwardly,” “upwardly,” etc.) should be construed to refer to the orientation as then described or as shown in the drawing figure under discussion. These relative terms are for convenience of description and normally are not intended to require a particular orientation. Terms including “inwardly” versus “outwardly,” “longitudinal” versus “lateral” and the like are to be interpreted relative to one another or relative to an axis of elongation, or an axis or center of rotation, as appropriate. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise. The term “operatively connected” is such an attachment, coupling or connection that allows the pertinent structures to operate as intended by virtue of that relationship.

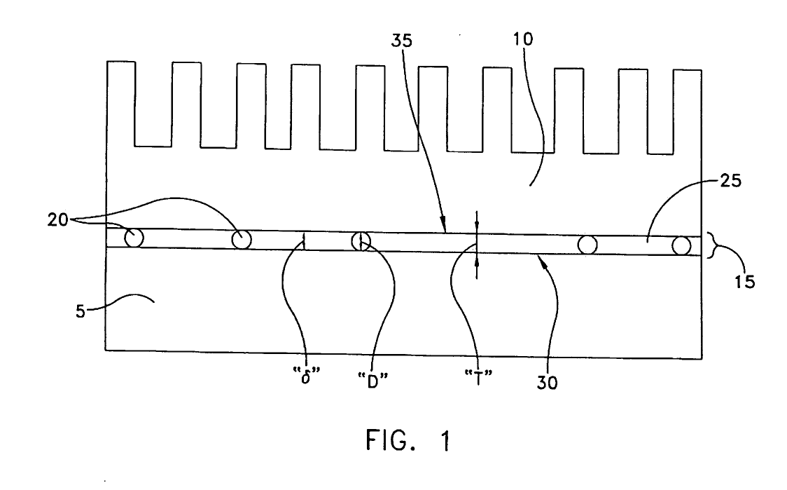

Referring to FIG. 1, a heat source 5 and heat sink 10 are shown with a thermally conductive, electrically insulating layer 15 disposed therebetween. Thermally conductive, electrically insulating layer 15 can be a mixture of a thermally conductive, electrically insulating heat transfer material 25 (e.g. thermal paste or grease), and a quantity of discretely sized spacer particles 20. The paste or grease component 25 serves to facilitate conduction of heat from the source to the sink, while the spacer particles 20 serve to maintain a precisely controlled dimensional offset between the two. Maintaining close control over the dimensional offset “σ” is desirable for at least two reasons. First, it allows for the precise calculation of actual heat transfer between the source and the sink, and second, it serves to prevent the discharge of electricity from the sink to the source where both components are made of a charge conductive material. This is of particular importance where the heat source is an electrical device, such as an IC.

For purposes of the present discussion, the heat source 5 may be any of a variety of electrical devices, or components of electrical devices, such as ICs, chip packages, printed circuit boards, or the like, and thus it will be appreciated that the type of heat source is not critical to the invention. Like the heat source 5, the heat sink 10 can be any appropriate heat sink known in the art, including air cooled metal fins or plates, liquid cooled plates, phase change heat sinks, heat pipes, etc.

Thermally conductive, electrical insulating layer 15 can comprise an appropriate thermally conductive, electrical insulating heat transfer material 25 known in the art combined with an appropriate quantity of specifically sized spacer particles 20. In one embodiment, heat transfer material 25 comprises a thermal grease, a thixotropic thermal compound, epoxies and other compounds that are applied in a fluid state and which later harden, or other thermally conductive flowable compound known in the art. The spacer particles 20 may comprise generally spherical particles of thermally conductive or thermally non-conductive material. Although spherical particles are preferred, some irregularity in spherical shape may be acceptable. Likewise, particles having other shapes can be used (e.g. triangular, etc.) as long as they are susceptible to maintaining a selected spacing between the heat transfer surfaces in use. Spacer particles 20 also should be substantially non-compressible and should retain their shape and size when subjected to loads expected between the heat source 5 and heat sink 10 during normal use. In one embodiment, spacer particles 20 are made of an electrically insulating inorganic material, such as glass or ceramic spheres. In another embodiment, spacer particles may comprise a highly cross-linked, high T_{g} organic material.

It is generally desirable that particles 20 have a narrow size distribution in order to ensure a predictable spacing between the heat source and sink. In one embodiment, spacer particles 20 are essentially monodisperse. Where the conductive layer 15 is comprised of a heat transfer material 25 which itself has a particulate filler material, the particle size of spacer particles 20 should be substantially larger than the largest filler particle of the heat transfer material 25. In one embodiment, the size of spacer particles 20 can range from about 0.002 inches to about 0.100 inches (i.e. 2 mils to 100 mils). In another embodiment, the size of spacer particles 20 can range from about 0.004 inches to about 0.050 inches (i.e. about 4 mils to about 50 mils).

In yet another embodiment, the size of spacer particles 20 can be selected based on a specific voltage standoff requirement between the heat source and heat sink. Thus, the selected particle size (in mils) equals the desired Safety Factor multiplied by the required voltage standoff (in volts) divided by the dielectric strength (in kVolts/mils) of the spacer particle 20 material.

Examples of appropriate thermal grease or thixotropic thermal compounds are those sold by Emerson & Cuming under the trademark ECCOTHERM and by Shin-Etsu Microsi, Inc. with the designation G-749. Examples of filler materials include Al, Cu, and Ag. The thermal grease liquid binder material may be a compatible, insulating non-aqueous liquid having low viscosity. The term “compatible” should be taken to mean that the liquid carrier utilized will not interfere with the other components (e.g., it should be non-corrosive). Examples of suitable carriers are paraffinic hydrocarbons, such as mineral oil, Silicone Oils, e.g., polydimethyl siloxanes, mixtures of glycerides, halogenated hydrocarbons, olefinic hydrocarbons, aromatic hydrocarbons, polymeric fluids, and mixtures of two or more of the above carriers. In general, the carrier should provide a continuous phase which in conjunction with the dispersant separates and lubricates the particles. It will be appreciated that the specific thermally conductive material used is not critical, but should be such that it provides a desired rate of heat transfer between the heat source and heat sink, while also providing the desired electrical insulation between the two.

Examples of acceptable ceramic spacer particles are SiC, AlN, BN, Diamond, VB, VB₂, Al.₂O₃, ZnO, MgO, and SiO₂, although others may also be used. Ceramic materials are desirable because they provide excellent electrical insulation properties. Mixtures of different types of thermally conductive spacer particles may also be used. Alternatively, mixtures of metallic and ceramic spacer particles may allow the dielectric strength and thermal conductivity of the conductive layer 15 to be tailored to a desired value. Ultimately, the conductive layer 15 should be highly thermally conducting, with a thermal conductivity of at least about 1.0 Watt/mK. In a preferred embodiment, the conductive layer 15 should have a thermal conductivity of about 30 Watt/mK or greater.

As shown in FIGS. 1-3, conductive layer 15 has a thickness “T” substantially equal to the diameter “D” of the spacer particles 20, which in the figures are spherically shaped particles. As shown in FIGS. 1-3, multiple spacer particles 20 are positioned in a single layer within conductive layer 15. The quantity of spacer particles 20 in conducting layer 15 should be selected to provide sufficient support between the heat source 5 and sink 10 during operation. In one embodiment, spacer particles 20 comprise less than about 1% by volume of conductive layer 15. In another embodiment, spacer particles 20 comprise less than about 10% of the volume of conductive layer 15.

Since the spacer particles can have a coefficient of thermal conductivity that differs from that of the heat transfer material 25, minimizing the total quantity of spacer particles 20 can minimize the overall effect on the thermal conductivity of conductive layer 15. In one embodiment, the quantity of spacer particles 20 is sufficiently low that the thermal conductivity of layer 15 is substantially the same as the heat transfer material 25. In another embodiment, the quantity of spacer particles 20 is such that the thermal conductivity of layer 15 is about 1%-10% less than the thermal conductivity of the heat transfer material 25. Likewise, the spacer particle 20 material can be selected to reduce or minimize the impact on the thermal conductivity of layer 15.

In use, the heat source and sink are connected by thermally conductive, electrically insulating layer 15 by adding and mixing a desired quantity spacer particles 20 to a selected heat transfer material 25. Subsequently, a quantity of the mixed material is applied to the surface 30 of heat source 5. Heat sink 10 is then placed over insulating layer 15 to engage a contact surface 35 of the sink 10 with the layer 15. Additional pressure is applied until the spacer particles 20 contact the associated surfaces of the heat source 5 and heat sink 10. During this application process, the layer 15 fills the space between the source and sink, eliminating air pockets between the two. The final layer 15 will comprise a single layer of spacer particles 20, providing an gap “σ” between the heat source 5 and heat sink 15 that is substantially equal to the diameter “D” of the spacer particles 20. As previously noted, although the illustrated embodiment shows spherical spacer particles 20, spacer particles having other shapes (e.g. triangles, etc.) may alternatively be used as long as they are capable of providing a specified, repeatable gap “σ” between the heat transfer surfaces of the source and sink.

Separating the heat source 5 and sink 10 by a known, repeatable offset ensures that the heat transfer flux between the source and sink can be optimized, while ensuring adequate voltage standoff. At the same time, the impact of manufacturing tolerance stack-up is minimized.

In some applications, the heat transfer material 25 including the spacer particles 20 can be applied to both the heat source 5 and heat sink 10 surfaces prior to joining the two. Alternatively, heat transfer material 25 can be deposited onto one or more of the surfaces 30, 35, followed by the application of spacer particles 20 onto the surface of the heat transfer material 25. This technique could be used to minimize the total number of spacer particles 20 used, while still ensuring that uniform support is provided between the heat source and sink. As will be appreciated by those of skill in the art, other appropriate application methods can also be employed to provide a uniform conductive layer 15 comprising a single layer of spacer particles 20.

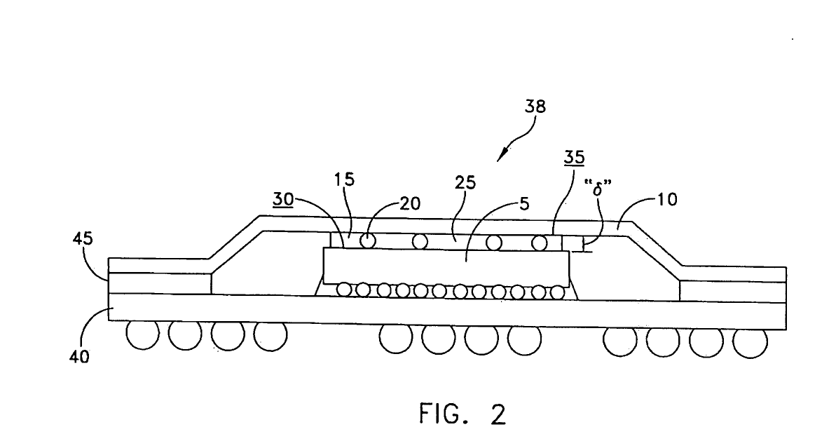

Once the conductive layer 15 has been disposed between the heat source 5 and heat sink 10, various arrangements can be used to hold the pieces together. In some instances, this function can be performed by the component package. As shown in FIG. 2, contact between the heat source and sink surfaces 30, 35 and layer 15 is maintained within flip chip package 38 using an appropriate adhesive 45. As illustrated, the heat source 5 and heat sink 10 are connected via insulating layer 15 (comprising heat transfer component 25 and a spacer particulate component 20) near the center of the package 38. A portion of the heat sink 10 extends laterally beyond the edges of the heat source 5 toward the lateral edges of the package, where it is fixed to package structure 40 using adhesive 45 as previously noted.

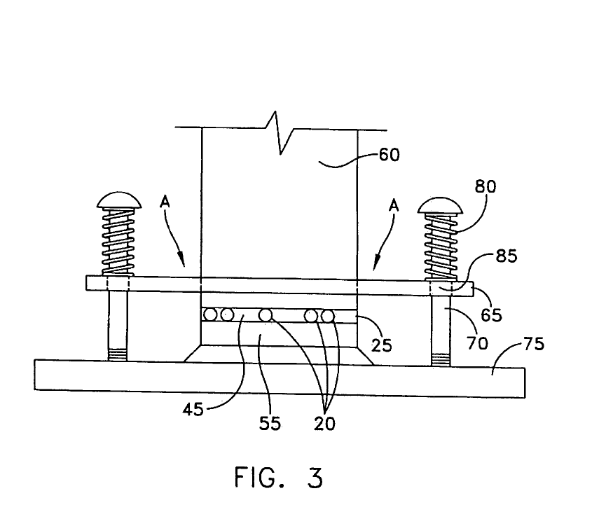

Referring to FIG. 3, a further structural application is shown in which heat source 55 and heat pipe 60 are thermally coupled using an insulating layer 15 (comprising a heat transfer component 25 and a spacer particulate components 20). The package of this example utilizes a spring mechanism to ensure continued engagement between the heat source and the heat pipe. Specifically, a pressure plate 65 is engaged with heat pipe 60 and comprises a pair of openings 85 within which the respective shanks of a pair of bolts 70 are received. The threaded portions of the bolts 70 are engaged within threaded bores in the base 75. Coil springs 80 are disposed about the bolts 70 and are captured between the bolt heads and the top surface of the plate 65 to provide a biasing force that tends to press the plate away from the bolt heads and toward the base 75. This biasing force thus presses the heat pipe 60 toward the heat source 55 to maintain the two in contact with each other via conductive layer 15. This biasing force ensures that the desired offset between the components is maintained. It is noted that although the example of FIG. 3 illustrates the use of coil springs, other appropriate biasing arrangements known in the art may be used to apply the desired compressive force between the components.

Additionally, it should be understood that for some applications, conductive layer 15, including paste component 25 and spacer particles 20, can be electrically conductive. The degree of electrical conductance can be carefully controlled through the selection of an appropriate conductive paste and/or conductive spacer particle materials. Thus, metallic fillers may be provided within the paste and/or metallic spacer particles may be used so as to provide for grounding and EMI isolation.

Accordingly, it should be understood that the embodiments disclosed herein are merely illustrative of the principles of the invention. Various other modifications may be made by those skilled in the art which will embody the principles of the invention and fall within the spirit and the scope thereof.

1. A thermally conductive composition for controlling heat transfer between first and second components, comprising:
a flowable component and a plurality of spacer members, the spacer members being of substantially uniform size and having a first dimension, the spacer members further being substantially incompressible;
wherein the first dimension is selectable to provide an offset between the first and second components when a quantity of the composition is disposed between opposing surfaces of the components and the surfaces are engaged with the plurality of spacer members, and wherein the flowable component is selectable to provide a desired rate of heat transfer between the first and second components when the first and second components are separated by said offset.

2. The composition of claim 1, wherein the flowable component comprises thermal grease or thermal paste.

3. The composition of claim 1, wherein the spacer members comprise a ceramic or glass material.

4. The composition of claim 1, wherein the first and second components are metallic, and the first dimension corresponds to a minimum voltage standoff between the components.

5. The composition of claim 4, wherein the first dimension is selected according to the formula:
First Dimension (mils)=(Factor of Safety)×(Voltage Standoff (volts))/(Particle Dielectric Strength (volts/mil)).

6. The composition of claim 1, wherein the first dimension is in the range of from about 2 mils to about 100 mils.

7. The composition of claim 6, wherein the first dimension is in the range of from about 4 mils to about 50 mils.

8. A component structure comprising:
a heat source having a major surface;
a heat sink having a major surface oriented parallel to the heat source major surface; and
a thermally conductive layer disposed between the heat source and heat sink major surfaces, the thermally conductive layer comprising a flowable component and a particulate component, the flowable component having a first coefficient of thermal conductivity, the particulate component comprising a plurality of spacer members of substantially uniform size, each of the plurality of spacer members having a first dimension, the spacer members further being substantially incompressible
wherein the major surfaces are offset by the layer of thermally conductive material by a distance substantially equal to the first dimension of the spacer members.

9. The composition of claim 8, wherein the flowable component comprises thermal grease or thermal paste.

10. The composition of claim 9, wherein the spacer members comprise a ceramic or glass material.

11. The composition of claim 8, wherein the heat source and heat sink are comprised of electrically conductive material, and the first dimension corresponds to a minimum voltage standoff between the first and second components.

12. The composition of claim 11, wherein the first dimension is selected according to the formula:
First Dimension (mils)=(Factor of Safety)×(Voltage Standoff (volts))/(Particle Dielectric Strength (volts/mil)).

13. The composition of claim 8, wherein the first dimension is in the range of from about 2 mils to about 100 mils.

14. The composition of claim 13, wherein the first dimension is in the range of from about 4 mils to about 50 mils.

15. A method of providing a desired heat transfer between first and second components, comprising:
providing a heat source having a contact surface;
providing a heat sink having a contact surface;
providing a thermally conductive material comprising a flowable component and a particulate component, the particulate component comprising a plurality of spacer members of substantially uniform size, each of said plurality of spacer members having a first dimension, the spacer members further being substantially incompressible; and
engaging the contact surfaces of the heat source and heat sink with a layer of the thermally conductive material;
wherein said step of engaging the contact surfaces further comprises:
placing a quantity of the thermally conductive material on one of the contact surfaces, and
drawing the contact surfaces together until the contact surfaces engage the plurality of spacer members to provide an offset between the surfaces that is substantially equal to the first dimension of the plurality of spacer members.

16. The method of claim 15, wherein the step of engaging the contact surfaces further comprises placing a quantity of the flowable component on at least one of the contact surfaces, then placing the plurality of spacer members on the flowable component prior to the step of drawing the contact surfaces together.

17. The method of claim 16, wherein said step of placing the plurality of spacer members on the flowable component comprises distributing a quantity of spacer members substantially evenly across a surface of the flowable component.

18. The method of claim 15, wherein the thermal conductivity of the thermally conductive material is substantially equal to thermal conductivity of the flowable component.

19. The method of claim 15, wherein the thermally conductive material is substantially electrically insulative.

20. The method of claim 15, wherein the step of providing a thermally conductive material comprises the step of selecting the first dimension of the plurality of spacer members according to the formula:
First Dimension (mils)=(Factor of Safety)×(Voltage Standoff (volts))/(Particle Dielectric Strength (volts/mil)).

21. The method of claim 15, wherein the first dimension is in the range of from about 2 mils to about 100 mils.

22. The method of claim 21, wherein the first dimension is in the range of from about 4 mils to about 50 mils.

23. The method of claim 15, further comprising the step of applying a compressive force to the heat source and heat sink to fix maintain the source and sink in position relative to each other.

24. The method of claim 23, wherein the compressive force is applied using a spring assembly.

25. The method of claim 23, wherein the compressive force is applied using an adhesive.
